(19) United States
(12) Patent Application Publication
(10) Pub. No.: US 2013/0037894 A1
(43) Pub. Date: Feb. 14, 2013

(54) METHOD FOR FABRICATING MAGNETIC TUNNEL JUNCTION

(71) Applicant: Su Ock CHUNG, Seoul (KR)

(72) Inventor: Su Ock CHUNG, Seoul (KR)

(21) Appl. No.: 13/336,120

(22) Filed: Dec. 23, 2011

(30) Foreign Application Priority Data
Aug. 9, 2011 (KR) 10-2011-0078968

(51) Int. Cl. H01L 29/82; H01L 21/02

(52) U.S. Cl. 257/421; 438/3; 257/E21.002; 257/E29.323

(57) ABSTRACT

In a method for fabricating a magnetic tunnel junction, a fixed layer, a tunnel insulating layer, a free layer, and an anti-etch layer are formed on a substrate. A sacrificial layer having a hole is formed on the anti-etch layer. An upper electrode is buried in the hole. The sacrificial layer is removed. The anti-etch layer, the free layer, the tunnel insulating layer, and the fixed layer are etched using the upper electrode as a mask.

### CROSS-REFERENCE TO RELATED APPLICATIONS

The present application claims priority of Korean Patent Application No. 10-2011-0078968, filed on Aug. 9, 2011, which is incorporated herein by reference in its entirety.

### BACKGROUND

1. Field

Exemplary embodiments of the present invention relate to a method for fabricating a magnetic tunnel junction, and more particularly, to a method for fabricating a magnetic tunnel junction, which prevents damage from being caused in a patterning process.

2. Description of the Related Art

Semiconductor devices are devices for electronically storing data. The semiconductor devices are used as storage media in computers, cellular phones, broadcasting devices, education and entertainment devices, and the like. A semiconductor device appeared in the market in 1971, and the memory capacity of the semiconductor device was 1 Kbits. Thereafter, the memory capacity of semiconductor devices has been remarkably developed, for example, it has been increased fourfold every two or third years.

Semiconductor devices have been developed, focusing on excellent data access and non-volatile data storage. As a result, a spin transfer torque random access memory (STTRAM) has been developed. The STTRAM is a semiconductor device using the quantum mechanical effect, i.e., magnetoresistance. The STTRAM has such characteristics as the free data access of the DRAM and the non-volatile data storage of the flash memory.

The STTRAM includes a magnetic tunnel junction for storing data. The magnetic tunnel junction includes a lower electrode, a fixed layer, a tunnel insulating layer, a free layer, and an upper electrode, and the magnetoresistance (MR) is changed depending on magnetization directions of the fixed layer and the free layer. The STTRAM senses a change in magnetoresistance and reads whether data stored in the magnetic tunnel junction is 1 or 0.

The STTRAM is formed by sequentially laminating the lower electrode, the fixed layer, a tunnel insulating layer, the free layer, and the upper electrode, first etching the upper electrode, and then etching the other layers using the etched upper electrode as an etch barrier (mask).

However, since the free layer is exposed in the etching of the upper electrode, the free layer may be damaged in a cleaning process for removing etch residues. Therefore, a technique for preventing such damage from being caused is being developed.

### SUMMARY

An embodiment of the present invention is directed to a method for fabricating a magnetic tunnel junction, which prevents damage from being caused in a patterning process.

In accordance with an embodiment of the present invention, a method for fabricating a magnetic tunnel junction includes forming a fixed layer, a tunnel insulating layer, a free layer and an anti-etch layer on a substrate, forming a sacrificial layer having a hole on the anti-etch layer, burying an upper electrode in the hole, removing the sacrificial layer, and etching the anti-etch layer, the free layer, the tunnel insulating layer, and the fixed layer using the upper electrode as a mask.

In accordance with another embodiment of the present invention, a magnetic tunnel junction includes a fixed layer on a substrate, a tunnel insulating layer formed on the fixed layer, a free layer formed on the tunnel insulating layer, and an anti-etch layer formed on the free layer.

### BRIEF DESCRIPTION OF THE DRAWINGS

FIGS. 1a to 1i illustrates plan views of a magnetic tunnel junction and sectional views taken along lines I-I′ of the respective plan views to illustrate a method for fabricating the magnetic tunnel junction in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

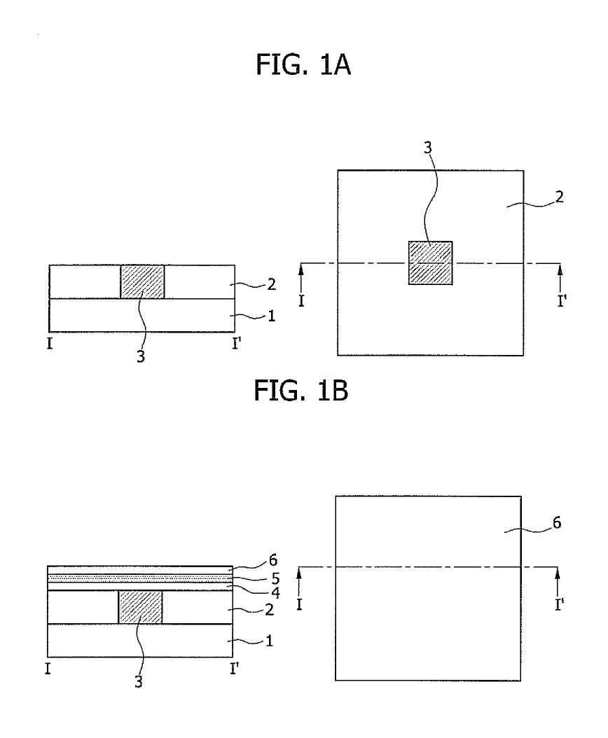

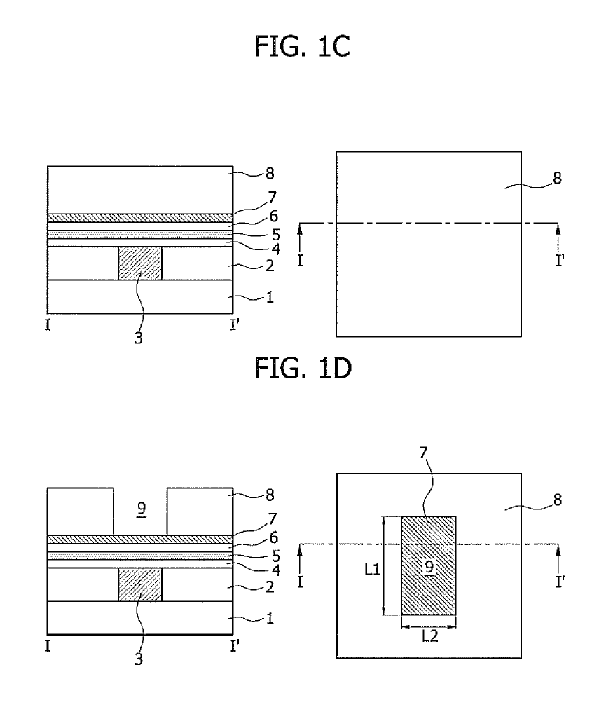

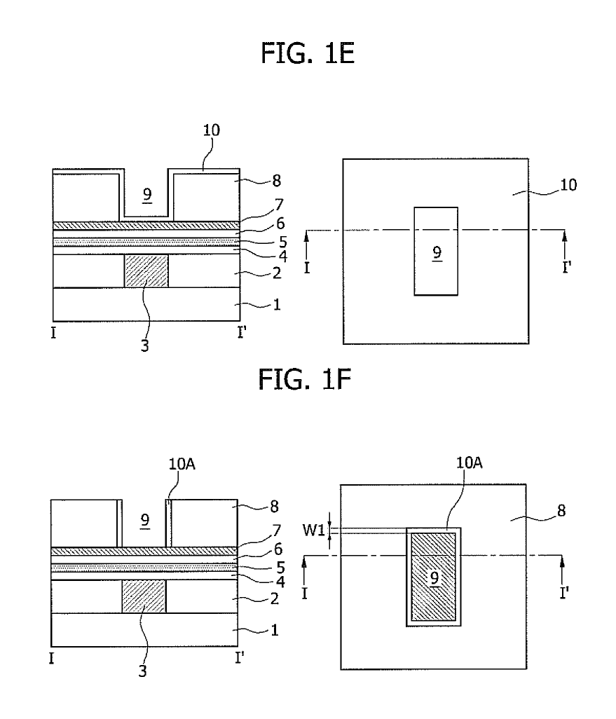

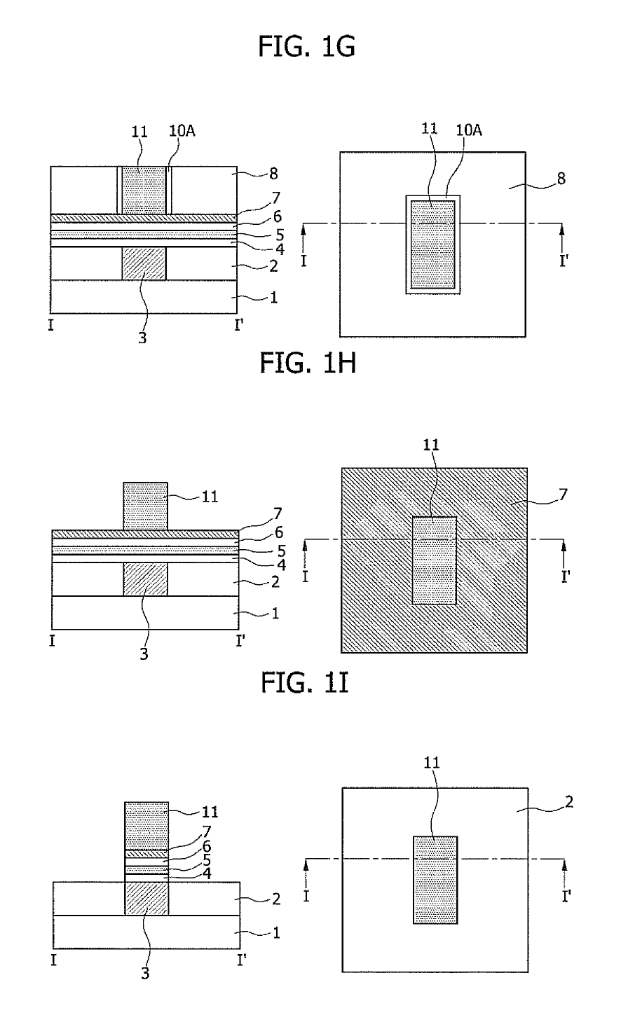

FIGS. 1a to 1i illustrates plan views of a magnetic tunnel junction and sectional views taken along lines I-I′ of the respective plan views to illustrate a method for fabricating the magnetic tunnel junction in accordance with an embodiment of the present invention.

As illustrated in FIG. 1A, a first interlayer insulating layer 2 is formed on a substrate having a bottom layer 1 formed thereon.

The bottom layer 1 includes a plurality of wells, an isolation layer, and a transistor. The first interlayer insulating layer 2 functions to insulate layers from each other. To this end, the first interlayer insulating layer 2 may be at least one of oxide-based material layers, e.g., a boro silicate glass (BSG) layer, a boro phospho silicate glass (BPSG) layer, a phosphor silicate glass (PSG) layer, a tetra ethyl ortho silicate (TEOS) layer, a high density plasma (HDP) oxide layer, and a spin on glass (SOG) layer.

Subsequently, a first contact plug 3 is formed to pass through the first interlayer insulating layer 2.

The first contact plug 3 is formed as a conductive layer. One side of the first contact plug 3 comes in contact with a junction region of the transistor in the bottom layer 1, and the other side of the first contact plug 3 comes in contact with the magnetic tunnel junction. In this case, the first contact plug 3 may be completely overlapped with the magnetic tunnel junction or partially overlapped with the magnetic tunnel junction.

As illustrated FIG. 1B, a first ferromagnetic layer 4, an insulating layer 5, and a second ferromagnetic layer 6 are sequentially formed on the substrate having the first contact plug 3 formed thereon.

The first ferromagnetic layer 4 is a thin film for severing as a fixed layer of which magnetization direction is fixed, and it may include a pinning layer and a pinned layer. The pinning layer functions to fix the magnetization direction of the pinned layer. To this end, the pinning layer is formed as a thin film made of at least one selected from the group consisting of IrMn, PtMn, MnO, MnS, MnTe, MnF₂, FeF₂, FeCl₂, FeO, CoCl₂, CoO, NiCl₂, and NiO. The magnetization direction of the pinned layer is fixed by the pinning layer. To this end, the pinned layer is formed as a thin film made of at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO, and Y₃Fe₅O₁₂. The insulating layer 5 is a thin film for serving as a tunnel insulating layer, and it may be an MgO layer. Alternatively, the insulating layer 5 may be formed as a semiconductor layer made of a Group-IV element in a periodic table of elements, or it may be formed by adding a Group-III or Group V element such as B, P, and As to the semiconductor layer so as to control the electric conductivity thereof. The second ferromagnetic layer 6 is a thin film for serving as a free layer of which magnetization direction is changed depending on a direction of current supplied thereto. To this end, the second ferromagnetic layer 6 is formed as a thin film made of at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO, and Y₃Fe₅O₁₂.

A lower electrode may be further interposed between the first contact plug 3 and the first ferromagnetic layer 4.

As illustrated in FIG. 1C, an anti-etch layer 7 and a sacrificial layer 8 are formed on the second ferromagnetic layer 6.

The anti-etch layer 7 is a thin film for preventing damage to the second ferromagnetic layer 6. The anti-etch layer 7 is formed as a conductive layer. For example, the anti-etch layer 7 may be an oxide electrode or may includes Ru or Ir.

The sacrificial layer 8 may be at least one of oxide-based material layers, e.g., a BSG layer, a BPSG layer, a PSG layer, a TEOS layer, an HDP oxide layer, and an SOG layer.

As illustrated in FIG. 1D, a hole 9 is formed by selectively etching the sacrificial layer 8.

The selective etching of the sacrificial layer 8 includes a process of forming a mask pattern having an opening for the area of the sacrificial layer 8 in which the hole 9 is to be formed and then etching the sacrificial layer 8 using the mask pattern as an etching barrier (mask). The longitudinal length L1 of the hole 9 may be longer than the lateral length L2 of the hole 9 so that the magnetization direction is formed in a uniform and constant direction.

As illustrated in FIG. 1E, an insulating layer 10 is deposited on the substrate having the hole 9 formed thereon. The insulating layer 10 is a thin film having high etch selectivity to the sacrificial layer 8, and it may be, for example, a nitride layer.

As illustrated in FIG. 1F, a spacer pattern 10A is formed on a sidewall of the hole 9 by etching the insulating layer 10.

The etching of the insulating layer 10 may be performed through a blanket etch or etch back process. The thickness W1 of the spacer pattern 10A functions to adjust the sectional area of the hole 9. For example, the area of the hole 9 decreases when the thickness W1 of the spacer pattern 10A is large, and the area of the hole 9 increases when the thickness W1 of the spacer pattern 10A is small.

As illustrated in FIG. 1G, an upper electrode 11 is formed in the hole 9.

The forming of the upper electrode 11 includes a process of forming a conductive layer so that the hole 9 is completely filled with the conductive layer and then planarizing the conductive layer. The planarization may be performed through a chemical mechanical polishing (CMP) process. The upper electrode 11 serves as an electrode for supplying current to the magnetic tunnel junction and a mask pattern for patterning the magnetic tunnel junction. The processes of forming the sacrificial layer 8, the hole 9, and the upper electrode 11 are also referred as a damascene process.

As illustrated in FIG. 1H, the sacrificial layer 8 and the spacer pattern 10A are removed. Accordingly, the upper electrode 11 is exposed to the outside.

Subsequently, a cleansing process is performed so as to remove etch residues generated in the process of removing the sacrificial layer 8 and the spacer pattern 10A. The cleaning liquid may damage the second ferromagnetic layer 6 in the conventional cleaning process. However, in the embodiment of the present invention, the anti-etch layer 7 is disposed on the second ferromagnetic layer 6, and hence the second ferromagnetic layer 6 may be prevented from being damaged by the cleaning liquid.

Further, since the anti-etch layer 7 is formed as the conductive layer, the anti-etch layer 7 may sufficiently function to supply current to the second ferromagnetic layer 6.

As illustrated in FIG. 1I, the anti-etch layer 7, the second ferromagnetic layer 6, the insulating layer 5, and the first ferromagnetic layer 4 are etched using the upper electrode 11 as an etch barrier (mask). Accordingly, the magnetic tunnel junction is formed.

As described above, in accordance with the embodiment of the present invention, the anti-etch layer 7 is interposed between the upper electrode 11 and the second ferromagnetic layer 6, so that the second ferromagnetic layer 6 may be prevented from being damaged by the cleaning liquid. Further, in order to effectively control the lateral and longitudinal lengths of the magnetic tunnel junction, the upper electrode 11 is not etched but buried in the hole. Since it is difficult to pattern the conductive layer used as the upper electrode 11, the upper electrode 11 may not have a desired profile after etching. However, if the upper electrode 11 is formed by burying the conductive layer in the hole, the desired profile may be sufficiently obtained. Here, the magnetization direction of the magnetic tunnel junction is to be formed uniformly in a constant direction. To this end, the magnetic tunnel junction has a high aspect ratio. For example, the longitudinal length is long and the lateral length is short. As the aspect ratio of the magnetic tunnel junction increases, the magnetization direction of the magnetic tunnel junction may be formed in a uniform direction. In accordance with the embodiment of the present invention, the area of the magnetic tunnel junction may be effectively controlled by adjusting the lateral and longitudinal lengths of the hole 9 in which the upper electrode is buried.

In the method for fabricating the magnetic tunnel junction in accordance with the present invention, an anti-etch layer is interposed between an upper electrode and a free layer, so that the free layer may be prevented from being damaged by cleaning liquid. Further, the upper electrode is not etched but buried in a hole so as to effectively control the longitudinal and lateral lengths of the magnetic tunnel junction. The magnetization direction of the magnetic tunnel junction is to be formed uniformly in a constant direction. To this end, the magnetic tunnel junction has a high aspect ratio. As the aspect ratio of the magnetic tunnel junction increases, the magnetization direction of the magnetic tunnel junction may be formed in a constant direction. Thus, the magnetic tunnel junction may obtain a magnetization direction uniform in a constant direction.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a magnetic tunnel junction, comprising:
forming a fixed layer, a tunnel insulating layer, a free layer, and an anti-etch layer on a substrate;
forming a sacrificial layer having a hole on the anti-etch layer;
burying an upper electrode in the hole;
removing the sacrificial layer; and
etching the anti-etch layer, the free layer, the tunnel insulating layer, and the fixed layer using the upper electrode as a mask.

2. The method of claim 1, wherein the anti-etch layer includes a conductive layer.

3. The method of claim 1, further comprising performing a cleaning process after the removing of the sacrificial layer.

4. The method of claim 1, wherein the longitudinal length of the hole is longer than the lateral length of the hole.

5. The method of claim 1, further comprising forming a spacer pattern on a sidewall of the hole after the forming of the sacrificial layer.

6. The method of claim 5, wherein the lateral and longitudinal lengths of the hole are controlled by adjusting the thickness of the spacer pattern.

7. The method of claim 5, wherein the spacer pattern is removed in the removing of the sacrificial layer.

8. The method of claim 1, wherein the anti-etch layer includes an oxide metal layer.

9. The method of claim 8, wherein the oxide metal layer is formed of Ru or Ir.

10. The method of claim 1, wherein the burying of the upper electrode in the hole includes:
forming a conductive layer to be filled in the hole; and
planarizing the conductive layer to form the upper electrode.

11. A magnetic tunnel junction, comprising:
a fixed layer on a substrate;
a tunnel insulating layer formed on the fixed layer;
a free layer formed on the tunnel insulating layer; and
an anti-etch layer formed on the free layer.

12. The method of claim 11, wherein the anti-etch layer includes a conductive layer or an oxide metal layer.

13. The method of claim 12, wherein the oxide metal layer is formed of Ru or Ir.
